(19) United States
(12) Patent Application Publication
(10) Pub. No.: US 2024/0321838 A1
(43) Pub. Date: Sep. 26, 2024

(54) DISPLAY PANEL, DISPLAY DEVICE, AND METHOD FOR MANUFACTURING DISPLAY PANEL

(71) Applicant: TIANMA ADVANCED DISPLAY TECHNOLOGY INSTITUTE (XIAMEN) CO., LTD., Xiamen (CN)

(72) Inventors: Peixuan CHEN, Xiamen (CN); Meng WANG, Xiamen (CN)

(73) Assignee: TIANMA ADVANCED DISPLAY TECHNOLOGY INSTITUTE (XIAMEN) CO., LTD., Xiamen (CN)

(21) Appl. No.: 18/731,367

(22) Filed: Jun. 3, 2024

(30) Foreign Application Priority Data
Jan. 19, 2024 (CN) 202410081056.8

(51) Int. Cl. H01L 25/075; H01L 33/00; H01L 33/60

(52) U.S. Cl. CPC H01L 25/0753; H01L 33/0095; H01L 33/60; H01L 2933/0058

(57) ABSTRACT

A display panel, a display device, and a method for manufacturing the display panel are provided. The display panel includes a substrate, light-emitting devices, a light reflecting part, and a light adjusting part. The light-emitting devices are spaced on one side of the substrate. The light reflecting part is at least partially located between adjacent light-emitting devices. The light adjusting part is arranged on one side of the light-emitting devices away from the substrate, and an orthographic projection of the light adjusting part on the substrate overlaps an orthographic projection of the corresponding light-emitting devices on the substrate. The light adjusting part includes a first surface away from the substrate, and the first surface protrudes away from the substrate. The light reflecting part and the light adjusting part can cooperate with each other to convert at least some of lateral beams into the forward beams.

This application claims priority to Chinese Patent Application No. 202410081056.8, titled “DISPLAY PANEL, DISPLAY DEVICE, AND METHOD FOR MANUFACTURING DISPLAY PANEL”, filed on Jan. 19, 2024 with the China National Intellectual Property Administration, which is hereby incorporated by reference in its entirety.

### FIELD

The present disclosure relates to the field of display devices, and in particular to a display panel, a display device and a method for manufacturing the display panel.

### BACKGROUND

Micro light emitting diodes (Micro-LED), i.e., arrays of miniaturized LED have advantages of good stability, long service life and low operating temperature, and further low power consumption, color saturation, short response time and strong contrast inherited from the LEDs. The Micro-LEDs are higher in brightness and lower in power consumption and therefore have broad application prospects.

However, the display devices employing the Micro-LEDs are still low in light utilization currently, which is desired to be improved.

### SUMMARY

A display panel, a display device, and a method for manufacturing the display panel are provided according to embodiments of the present disclosure provide, to improve the light utilization.

In one embodiment, a display panel is provided according to an embodiment of the present disclosure. The display panel includes a substrate, light-emitting devices, a light reflecting part, and a light adjusting part. The light-emitting devices are spaced on one side of the substrate. The light reflecting part is at least partially located between adjacent light-emitting devices. The light adjusting part is arranged on one side of the light-emitting devices away from the substrate, and an orthographic projection of the light adjusting part on the substrate overlaps an orthographic projection of the corresponding light-emitting devices on the substrate. The light adjusting part includes a first surface away from the substrate, and the first surface protrudes away from the substrate.

In one embodiment, a display device is provided according to an embodiment of the present disclosure. The display device includes the display panel as described above.

In one embodiment, a method for manufacturing a display panel is provided according to an embodiment of the present disclosure. The method includes: transferring light-emitting devices to one side of a substrate and arranging a light reflecting part between the adjacent light-emitting devices; and forming a light adjusting part on one side of the light-emitting device away from the substrate. An orthographic projection of the light adjusting part on the substrate overlaps an orthographic projection of the light-emitting device on the substrate. The light adjusting part includes a first surface away from the substrate. The first surface protrudes away from the substrate.

### BRIEF DESCRIPTION OF THE DRAWINGS

For clear illustration of the embodiments of the present disclosure, hereinafter drawings to be applied in embodiments of the present disclosure are briefly described.

FIG. 1 is a schematic cross-sectional structural diagram of a display panel in related technologies;

FIG. 2 is a schematic cross-sectional structural diagram of a display panel according to an embodiment of the present disclosure;

FIG. 3 is a schematic cross-sectional structural diagram of the display panel according to another embodiment of the present disclosure;

FIG. 4 is a schematic cross-sectional structural diagram of a display panel in in related technologies;

FIG. 5 is a schematic cross-sectional structural diagram of the display panel according to another embodiment of the present disclosure;

FIG. 6 is a schematic cross-sectional structural diagram of the display panel according to another embodiment of the present disclosure;

FIG. 7 is a schematic cross-sectional structural diagram of the display panel according to another embodiment of the present disclosure;

FIG. 8 is a schematic structural diagram of the display panel according to another embodiment of the present disclosure;

FIG. 9 is a schematic cross-sectional structural diagram of the display panel along A-A in FIG. 8;

FIG. 10 is a schematic cross-sectional structural diagram of the display panel according to another embodiment of the present disclosure;

FIG. 11 is a schematic cross-sectional structural diagram of the display panel according to another embodiment of the present disclosure;

FIG. 12 is a cross-sectional structural view of the display panel at a position Q in FIG. 11;

FIG. 13 is a schematic structural diagram of a display device according to an embodiment of the present disclosure;

FIG. 14 is a flow chart of a method for manufacturing a display panel according to an embodiment of the present disclosure;

FIGS. 15a to 15b each are a schematic structural diagram illustrating the manufacturing the display panel according to an embodiment of the present disclosure;

FIG. 16 is a flow chart of a method for manufacturing a display panel according to an embodiment of the present disclosure;

FIGS. 17a to 17c each are a schematic structural diagram illustrating the manufacturing the display panel according to an embodiment of the present disclosure;

FIG. 18 is a flow chart of a method for manufacturing a display panel according to an embodiment of the present disclosure; and

FIGS. 19a to 19b each are a schematic structural diagram illustrating the manufacturing the display panel according to an embodiment of the present disclosure.

Reference numerals:

| | | | |
|---|---|---|---|
| 10 | substrate; | 20 | light-emitting device; |
| 21 | light-emitting part; | 211 | light-emitting layer; |
| 212 | first semiconductor layer; | 213 | second semiconductor layer; |
| 22 | first electrode; | 23 | second electrode; |
| 24 | insulating layer; | 30 | light reflecting part; |
| 31 | reflecting division; | 40 | light adjusting part; |
| 50 | planarization part; | 60 | light-shielding part; |
| 70 | white glue material; | 80 | transparent adhesive layer; |
| L | micro light-emitting diode; | J | partition; |
| M1 | first surface; | M2 | second surface; |
| M3 | third surface; | M4 | fourth surface; |
| M5 | fifth surface; | M6 | sixth surface; |
| B | center; | E1 | first edge; |
| E2 | second edge; | A1 | active area; |
| A2 | transparent area; | X | first direction; |
| Y | second direction; | Z | thickness direction. |

### DETAILED DESCRIPTION

Hereinafter features and exemplary embodiments in various embodiments of the present disclosure will be described in detail. In order to clarify purposes, embodiments of the present disclosure, the present disclosure is described in conjunction with the drawings and specific embodiments. The specific embodiments described herein are only intended for explaining the present disclosure rather than limiting the present disclosure. Description of the following embodiments merely illustrates examples for facilitating understanding of the present disclosure.

The relationship terms “first”, “second” and the like are only used herein to distinguish one entity or operation from another, rather than to necessitate or imply that an actual relationship or order exists between the entities or operations. Furthermore, the terms such as “include”, “comprise” or any other variants thereof means to be non-exclusive. Therefore, a process, method, article or device including a series of elements include not only the disclosed elements but also other elements that are not clearly enumerated, or further include inherent elements in the process, method, article or device. Unless expressively limited, the statement “including a . . . ” does not exclude the case that other similar elements may exist in the process, method, article or device other than enumerated elements.

Compared with liquid crystal display panels and organic light-emitting display panels, display panels employing micro light emitting diodes (micro-LED) as light-emitting elements have advantages of high brightness, wide color gamut, long service life, and fast response. Micro-LED display panels, applied in vehicle-mounted transparent displays, benefit from smaller sizes and packaging structures without polarizing films. Therefore, the micro-LED display panels have unique advantages in transparency compared with other types of display panels.

However, the micro-LED display panels have many technical bottlenecks, one of which is low light utilization of micro-LEDs. The micro light-emitting diodes as light-emitting devices may emit 360° light beams. However, only some beams at a certain angles, i.e., forward beams, are actually used for luminous display, while lateral beams and light beams at other angles fails to contribute to the display, resulting in the low light utilization.

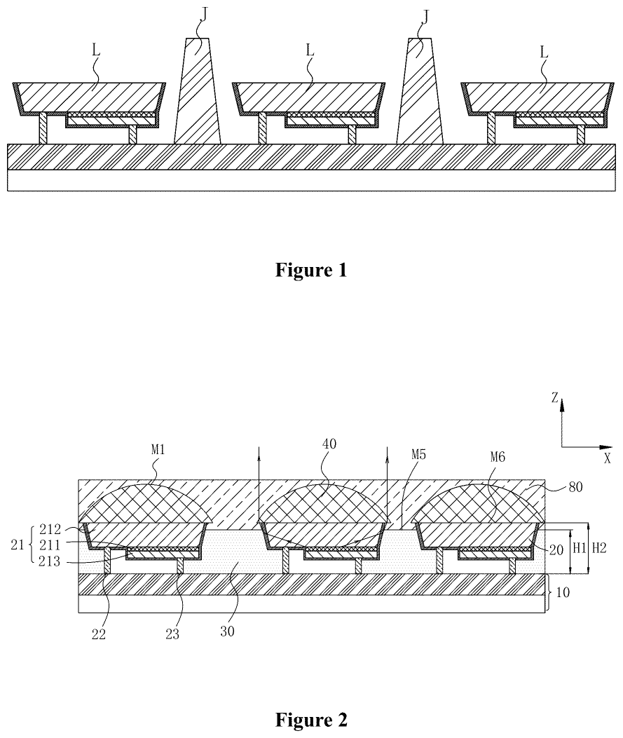

In the conventional technology, as shown in FIG. 1, a partition J is generally arranged around a micro light-emitting diode L. The partition J may absorb at least some of the lateral beams emitted by the micro light-emitting diode L to reduce crosstalk between the light beams emitted by different micro-light-emitting diodes L, resulting in low light utilization by the display panel. This adversely affects the display effects and power consumption.

In one embodiment, reference is made to FIG. 2, a display panel is provided according to an embodiment of the present disclosure. The display panel includes a substrate 10, multiple light-emitting devices 20, a light reflecting part 30 and a light adjusting part 40. The multiple light-emitting devices 20 are spaced on one side of the substrate 10. The light reflecting part 30 is at least partially located between adjacent light-emitting devices 20. The light adjusting part 40 is disposed on one side of the light-emitting device 20 away from the substrate 10. An orthographic projection of the light adjusting part 40 on the substrate 10 overlaps an orthographic projection of the corresponding light-emitting device 20 on the substrate 10. The light adjusting part 40 includes a first surface M1 away from the substrate 10, and the first surface M1 protrudes away from the substrate 10.

The substrate 10 mainly plays a supporting role. Other film structures and device structures are sequentially stacked on the substrate 10. The stacked arrangement here means that other film structures and device structures are arranged sequentially along a thickness direction Z of the substrate 10. The thickness direction Z of the substrate 10 is usually consistent with the thickness direction Z of other films. For ease of description, herein the thickness direction Z of the substrate 10 and the thickness direction Z of other films are illustrated in a same direction.

The light-emitting device 20 is a main structure configured to achieve display effects in the display panel, and may include a micro light-emitting diode. There are multiple light-emitting devices 20, and at least some of different light-emitting devices 20 may be configured to emit light of different colors. In one embodiment, the multiple light-emitting devices 20 may include a red light-emitting device 20 for emitting red light, a green light-emitting device 20 for emitting green light, and a blue light-emitting device 20 for emitting blue light.

Furthermore, the substrate 10 may include a multiple film structures that are stacked. The specific composition of the film structures inside the substrate 10 is not limited in the embodiment of the present disclosure. In one embodiment, the substrate 10 may include a stacked substrate and an array layer. A pixel driving circuit is disposed in the array layer, and is electrically connected to the light-emitting device 20 to control the light-emitting device 20 to emit light.

When the display panel displays a specific image, the light-emitting devices 20 emit light under the control of the pixel driving circuit. However, the light beams emitted by the light-emitting devices 20 does not completely exit from the display panel along the thickness direction Z. Instead, some of the beams exits from a lateral side of the light-emitting device 20. As a result, fewer light beams are emitted from the light-emitting device 20 in a forward direction, resulting in light utilization.

In an embodiment, the light reflecting part 30 and the light adjusting part 40 are both disposed inside the display panel, and cooperate with each other, thereby improving the light utilization of the display panel. In an embodiment, the light reflecting part 30 is at least partially located between adjacent light-emitting devices 20, that is, the light reflecting part 30 is at least partially located on the lateral side of the light-emitting device 20. The light reflecting part 30 is made of reflective material. At least some of the lateral beams emitted by the light-emitting device 20 are reflected by the light reflecting part 30 and then propagate to the light adjusting part 40.

The light adjusting part 40 includes a first surface M1 away from the substrate 10, and the first surface M1 protrudes away from the substrate 10. That is, a cross-sectional structure of the light adjusting part 40 may be in a shape similar to a convex lens, and then the light adjusting part 40 can combine light beams to a certain extent. Therefore, the light reflected by the light reflecting part 30 can be converged by the light adjusting part 40 when reaching the light adjusting part 40, and at least some of the lateral beams emitted by the light-emitting device 20 can be converted into forward beams with the cooperation of the light reflecting part 30 and the light adjusting part 40, thereby improving the light utilization of the display panel. FIG. 1 shows a propagation path corresponding to some of the lateral beams emitted by the light-emitting device 20.

The material of which the light reflecting part 30 is made is not limited in the embodiments of the present disclosure. Depending on different materials, the light reflecting part 30 may reflect all the light beams reaching the light reflecting part 30, or the light reflecting part 30 may only reflect some of the light beams reaching the light reflecting part 30, and absorb or transmit other light beams reaching the light reflecting part 30.

Herein a relative positional relationship between the light reflecting part 30 and the light-emitting device 20 is not limited. In one embodiment, the light reflecting part 30 may be disposed closely with the light-emitting device 20, or spaced apart from the light-emitting device 20 on a plane parallel to the substrate 10. The light reflecting part 30 may be completely located between adjacent light-emitting devices 20, or partially located between adjacent light-emitting devices 20 and partially located on a side of the light-emitting device 20 facing or away from the substrate 10.

In addition, the material of which the light adjusting part 40 is made is not limited herein, as long as the light adjusting part 40 is capable of light transmission and light converging. The positional relationship between the light adjusting part 40 and the light-emitting device 20 may have various forms. The light adjusting part 40 may be attached to, or spaced apart from the light-emitting device 20 in the thickness direction Z. The orthographic projection of one light adjusting part 40 on the substrate 10 may only overlap the orthographic projection of one light-emitting device 20 on the substrate 10, or overlap with the orthographic projection of multiple light-emitting devices 20 on the substrate 10, which is not limited herein.

In summary, herein the display panel includes the light reflecting part 30 and the light adjusting part 40, and at least some of the lateral beams emitted by the light-emitting device 20 can be reflected by the light reflecting part 30 and converged by the light adjusting part 40, and then converted into the forward beams. That is, at least some of the lateral beams are converted into the forward beams through cooperation of the light reflecting part 30 with the light adjusting part 40 in the display panel, thereby improving the light utilization of the display panel and improving the display effects.

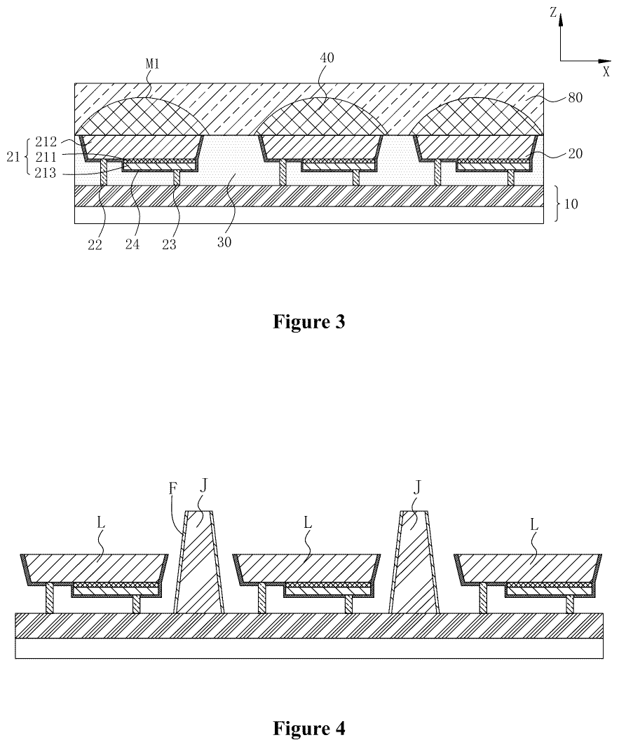

In some embodiments, reference is made to FIG. 3, the light reflecting part 30 is partially located on one side of the light-emitting device 20 facing the substrate 10.

A part of the light reflecting part 30 is located between adjacent light-emitting devices 20, and another part of the light reflecting part 30 has the orthographic projection on the substrate overlapping the orthographic projection of the light-emitting device 20 on the substrate 10, and is located on the side of the light-emitting device 20 facing the substrate 10. The part of the light reflecting part 30 located between adjacent light-emitting devices 20 may be connected to, or may be spaced apart from another part of the light reflecting part 30 located on the side of the light-emitting device 20 facing the substrate 10, which is not limited herein.

In addition to emitting the forward beams and the lateral beams, the light-emitting device 20 further emits light beams which propagate toward the substrate 10. On the above basis, in an embodiment, another part of the light reflecting part 30 is disposed on the side of the light-emitting device 20 facing the substrate 10, and part of the light emitted by the light-emitting device 20 propagating toward the substrate 10 may be reflected by the light reflecting part 30, changed in the propagation direction and reaches the light adjusting part 40. Therefore, the part of light is converted into the forward beams with the cooperation of the light reflecting part 30 and the light adjusting part 40, thereby further improving the light utilization of the display panel and improving the display effects.

In some embodiments, the light-emitting device 20 includes a light-emitting part 21, a first electrode 22 and a second electrode 23 located on a side of the light-emitting part 21 facing the substrate 10. The light reflecting part 30 is partially located between the first electrode 22 and the second electrode 23 of the same light-emitting device 20.

The light-emitting part 21 may include multiple film structures which are stacked. For example, the light-emitting part 21 may include a second semiconductor layer 213, a light-emitting layer 211 and a first semiconductor layer 212 that are sequentially stacked in a direction away from the substrate 10. The light-emitting layer 211 is a main component for emitting light. The first semiconductor layer 212 and the second semiconductor layer 213 are configured to drive and control the light-emitting layer 211 to emit light. Furthermore, the second semiconductor layer 213 includes, for example, an N-type semiconductor layer, the light-emitting layer 211 includes, for example, a multi quantum well (MWQ) structure, and the first semiconductor layer 212 includes, for example, a P-type semiconductor layer. These are not limited thereto.

The first electrode 22 and the second electrode 23 are connected to the first semiconductor layer 212 and the second semiconductor layer 213 respectively. The first electrode 22 and the second electrode 23 are both electrically connected to the pixel driving circuit, and receive corresponding power signals respectively under the control of the pixel driving circuit, thereby controlling the light-emitting layer 211 to emit light.

On the foregoing basis, the light reflecting part 30 is partially located between the first electrode 22 and the second electrode 23 in the same light-emitting device 20, and the light reflecting part 30 can be located on both the side face of the light-emitting device 20 and the side of the light-emitting device 20 facing the substrate 10, improving the reflection effect of the light reflecting part 30 on other light beams, besides the forward beams, emitted by the light-emitting device 20. Therefore, the light utilization of the display panel can be improved.

The light-emitting device 20 may further include other structures in addition to the light-emitting part 21, the first electrode 22 and the second electrode 23. The specific composition of the light-emitting device 20 is not limited herein. In an embodiment, the light-emitting device 20 may further include a buffer layer, an insulating layer 24 and other structures.

In some embodiments, reference is made to FIGS. 2 and 3, the light reflecting part 30 is attached to the light-emitting device 20.

The light reflecting part 30 is attached to the light-emitting device 20. Depending on the relative positional relationship between the light reflecting part 30 and the light-emitting device 20, the light reflecting part 30 may be formed together with the light-emitting device 20, and then the light reflecting part 30 and the light-emitting device 20 may be transferred to the substrate 10 as a whole. In one embodiment, the light reflecting part 30 and the light-emitting device 20 may be formed or transferred to the substrate 10 separately. After the transfer or formation is completed, the light reflecting part 30 and the light-emitting device 20 are attached to each other.

In an embodiment, the arrangement of the light-emitting device 20 being attached to the light reflecting part 30 facilitates a short distance between the light reflecting part 30 and the light-emitting device 20. Therefore, more lateral beams emitted by the light-emitting device 20 can be reflected by the light reflecting part 30, thereby improving the light utilization of the display panel.

In addition, in the conventional technology, as shown in FIG. 4, a size of an opening formed by the partition J located on a peripheral side of the micro-LED L is generally larger than the size of the micro-LED L, to meet transfer accuracy of the micro-LED L. Furthermore, a reflective layer F may be provided on a side of the partition J facing the micro-LED L, and may be configured to reflect some of the lateral beams emitted by the micro-LED L to change the propagation path. The reflective layer F and the micro-LED L may be spaced apart due to the influence of transfer accuracy, and part of the lateral beams emitted by the micro-LED L may not be transferred to the reflective layer F, but directly exit from the display panel.

In an embodiment, the light-emitting device 20 is attached to the light reflecting part 30, that is, no spaced is formed in the light reflecting part 30 for transferring the light-emitting device 20. Therefore, the preparation of the light reflecting part 30 does not consider the transfer accuracy of the light-emitting device 20, which can reduce the difficulty in manufacturing the display panel and improve the manufacturing yield of the display panel.

In addition, the light-emitting device 20 and the light reflecting part 30 are attached to each other, compared with the embodiments in which the two are spaced apart, more lateral beams emitted by the light-emitting device 20 can propagate to the light reflecting part 30 and be changed in propagation direction by the light reflecting part 30, thereby further improving the light utilization of the display panel.

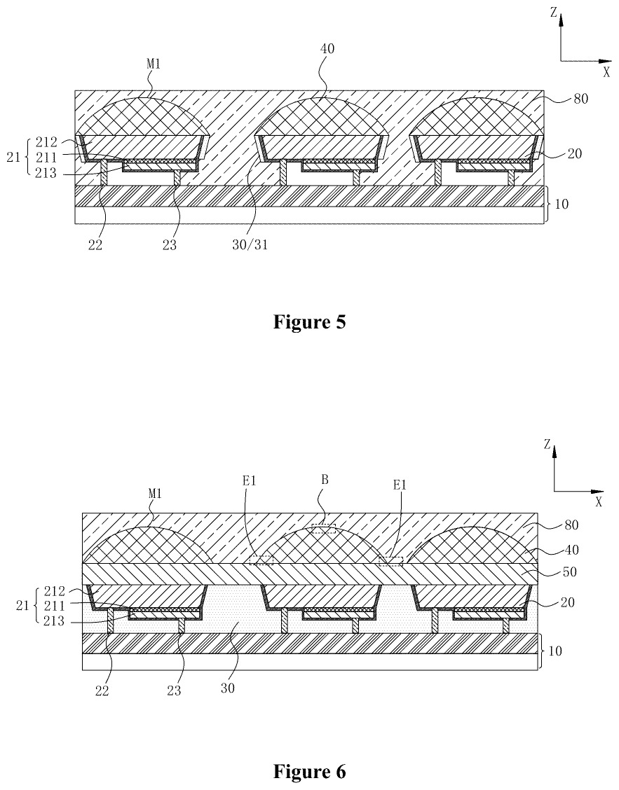

In some embodiments, reference is made to FIG. 5, the light reflecting part 30 includes multiple reflecting divisions 31, which are attached to the light-emitting device 20 in the first direction X. Adjacent reflecting divisions 31 are spaced apart from each other.

The first direction X may be the direction in which the multiple light-emitting devices 20 are arranged. The multiple light-emitting devices 20 may In one embodiment be arranged side by side in other directions other than the first direction X, which is not limited herein.

The light reflecting part 30 includes multiple reflecting divisions 31, which are arranged at intervals. The reflecting divisions 31 are arranged corresponding to the light-emitting devices 20, and are attached to the light-emitting devices 20 along the first direction X. The material composition of the reflecting divisions 31 is not limited herein. In an embodiment, the reflecting divisions 31 may include a metal material, and the metal material itself has a certain reflective ability. Therefore, the reflecting divisions 31 can reflect light.

Under the foregoing design, the reflecting divisions 31 may be integrated with the light-emitting device 20 during the preparation process of the light-emitting device 20 or after the light-emitting device 20 is completed, and then the light-emitting device 20 and the reflecting divisions 31 are transferred to the substrate 10 together, improving the reliability of the relative position between the reflecting division 31 and the light-emitting device 20, and thereby enhancing the reflection effect of the lateral beams emitted by the light-emitting device 20 on the reflecting divisions 31. Therefore, the light utilization and the display effect can be improved.

In some embodiments, as shown in FIG. 2, in the thickness direction Z of the substrate 10, a distance between the surface of the light reflecting part 30 away from the substrate 10 and the substrate 10 is not greater than a distance between the surface of the light-emitting device 20 away from the substrate 10 and the substrate 10.

The light reflecting part 30 includes a fifth surface M5 on a side away from the substrate 10, the light-emitting device 20 includes a sixth surface M6 on a side away from the substrate 10. Furthermore, the sixth surface M6 may be a surface of the first semiconductor layer 212 away from the substrate 10.

The distance H1 between the fifth surface M5 is less than or equal to the substrate and the distance H2 between the sixth surface M6 and the substrate 10. The fifth surface M5 may be a planar surface, and H1 is the distance between any point on the fifth surface M5 and the substrate 10 in the thickness direction Z. In one embodiment, the fifth surface M5 is a curved surface or other non-planar structure, and H1 is a maximum distance between the fifth surface M5 and the substrate 10 in the thickness direction Z. The distance H2 between the sixth surface M6 and the substrate 10 is similar to the above, which is not described in detail.

The fifth surface M5 is not larger than the sixth surface M6 in size in the thickness direction in conjunction with the drawings due to H2≥H1, which facilitates a small overall size of the light reflecting part 30 and the light-emitting device 20 in the thickness direction Z, thereby reducing the overall thickness of the display panel and facilitating a thinner and lighter display panel. Further, the light-emitting device 20 is less blocked by the light reflecting part 30, reducing the difficulty in transferring the light-emitting devices 20 to the substrate 10.

In some embodiments, the light reflecting part 30 includes white glue. Furthermore, the white glue may be made of at least one of titanium oxide and zinc oxide.

The white glue is reflective to a certain extent. Part of the lateral beams emitted by the light-emitting device 20 and illuminated on the white glue may be reflected by the white glue and propagate to the light adjusting part 40. Therefore, at least part of the lateral beams may be converted into the forward beams, which improves the light utilization of the display panel.

In addition, during the preparation of the display panel, the white glue is first in a flowing state. The flowing white glue may contact the light-emitting device 20, and then be solidified, and the solidified white glue is attached to the light-emitting device 20. In conventional technologies, the partition is generally a solid structure. Further, it is necessary to ensure the corresponding transfer accuracy of the micro-LEDs during the transferring micro-LEDs, to reduce the risk of contact between the partition and the micro-LEDs, and improve a yield of micro-LEDs after transferring.

The white glue and the partition both can separate different light-emitting devices 20. Therefore, the white glue in the embodiments of the present disclosure may replace the partition around the light-emitting device 20 in the conventional technology. Since the white glue itself may be attached to the light-emitting device 20, the arrangement of the white glue does not consider the transfer accuracy of the light-emitting device 20. The light-emitting devices 20 are unnecessarily transferred to a specific preset area, reducing the difficulty in manufacturing the display panel and improving the manufacturing yield of the display panel.

In some embodiments, reference is made to FIG. 6, the array substrate 10 further includes a planarization part 50 located between the light adjusting part 40 and the light-emitting device 20 in the thickness direction Z of the substrate 10.

The planarization part 50 may space the light adjusting part 40 and the light-emitting device 20 in the thickness direction Z, and the planarization part 50 is generally prepared before the light adjusting part 40. Therefore, the planarization part 50 may provide a flat surface for preparing the light adjusting part 40, to reduce the difficulty in preparing the light adjusting part 40 and improve a relative position reliability of the light adjusting part 40 compared to the light-emitting device 20.

The material of which the planarization part 50 is made is not limited herein. The foregoing content and the accompanying drawings illustrate that the forward beams emitted by the light-emitting device 20 pass through the planarization part 50, while the lateral beams emitted by the light-emitting device 20 may be reflected by the light reflecting part 30 and pass through the planarization part 50 to the light adjusting part 40. On this basis, the planarization part 50 is made of such material that the planarization part 50 has a certain transmittance, to meet light extraction requirements of the display panel.

In some embodiments, a refractive index of the planarization part 50 is less than a refractive index of the light adjusting part 40.

Based on the foregoing, the lateral beams emitted by the light-emitting device 20 may be reflected by the light reflecting part 30 and propagate to the planarization part 50 and the light adjusting part 40, and finally exit from the display panel.

On this basis, since the refractive index of the planarization part 50 is smaller than the refractive index of the light adjusting part 40, the light may first enter the film layer with a small refractive index and then propagate to the film layer with a large refractive index. A difference in refractive index between the planarization part 50 and the light adjusting part 40 can adjust and change the propagation path of the lateral beams, and the lateral beams is further converged and converted into the forward beams, thereby further improving the luminous efficiency of the display panel. This has strong practicality. In an embodiment, the refractive index of the planarization part 50 ranges from 1.3 to 1.65, and the refractive index of the light adjusting part 40 ranges from 1.7 to 1.9.

In some embodiments, the light-emitting device 20 includes a light-emitting layer 211. The refractive index of the light-emitting layer 211 is greater than the refractive index of the light adjusting part 40.

The light through mediums with different refractive indexes corresponds to different refraction angles. A large refractive index corresponds to a small refraction angle. On this basis, multiple light beams entering from a high-refractive medium to a low-refractive medium may spread relatively divergently, and multiple light beams entering from a low-refractive medium into a high-refractive medium may relatively converge.

The light-emitting layer 211 is a film structure configured to emit light in the light-emitting device 20, and the light is generally generated from the light-emitting layer 211. The refractive index of the light-emitting layer 211 is generally greater than the refractive index of the light adjusting part 40 due to limitations of materials and other factors. Furthermore, in a case that the light-emitting device 20 is too close to the light adjusting part 40 in the thickness direction Z, the difference in refractive index between the two renders that the light adjusting part 40 may not have a strong light gathering effect. That is, the problem of low light utilization of the display panel may still occur.

In an embodiment, the planarization part 50 separates the light-emitting device 20 and the light adjusting part 40 in the thickness direction Z, and the light-emitting layer 211 and the light adjusting part 40 may have a certain distance in the thickness direction Z, thereby reducing the impact of the difference in refractive index between the light-emitting layer 211 and the light adjusting part 40 on the direction of light propagation. Furthermore, the refractive index of the planarization part 50 is set to be smaller than the refractive index of the light adjusting part 40, thereby further adjusting and changing the propagation path of the lateral beams, and the lateral beams is further converged and converted into the forward beams, which improves the light utilization of the display panel. In an embodiment, the refractive index of the light-emitting layer 211 ranges from 2.1 to 2.6.

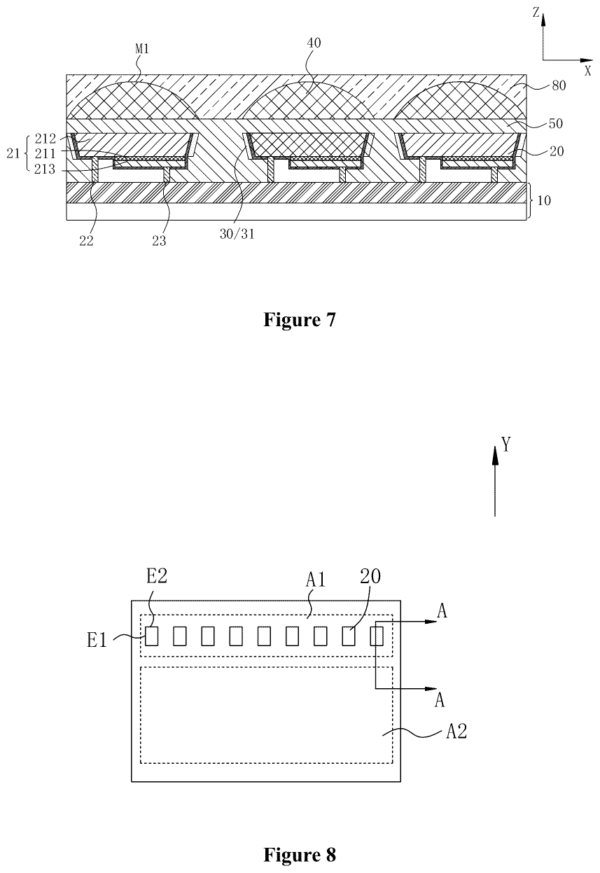

In some embodiments, reference is made to FIG. 7, the planarization part 50 is partially stuffed between adjacent light-emitting devices 20.

The light reflecting part 30 may have various forms based on the foregoing. For example, the light reflecting part 30 includes multiple reflecting divisions 31, which are independent of each other and spaced apart from each other. In such case, no light reflecting part 30 is stuffed between adjacent light-emitting devices 20, which may affect the subsequent preparation of film layers, for example, the light adjusting part 40.

In an embodiment, the planarization part 50 is partially stuffed between adjacent light-emitting devices 20, and gaps between the adjacent light-emitting devices 20 where the light reflecting part 30 is not provided can be filled up with the planarization part 50. Accordingly, the surface of the planarization part 50 away from the substrate 10 may be a flat planar structure, thereby providing a good film structure condition for other film structures on the side of the planarization part 50 away from the substrate 10, thereby reducing the difficulty in preparing the film structures such as the light adjusting part 40 and improving the preparation accuracy.

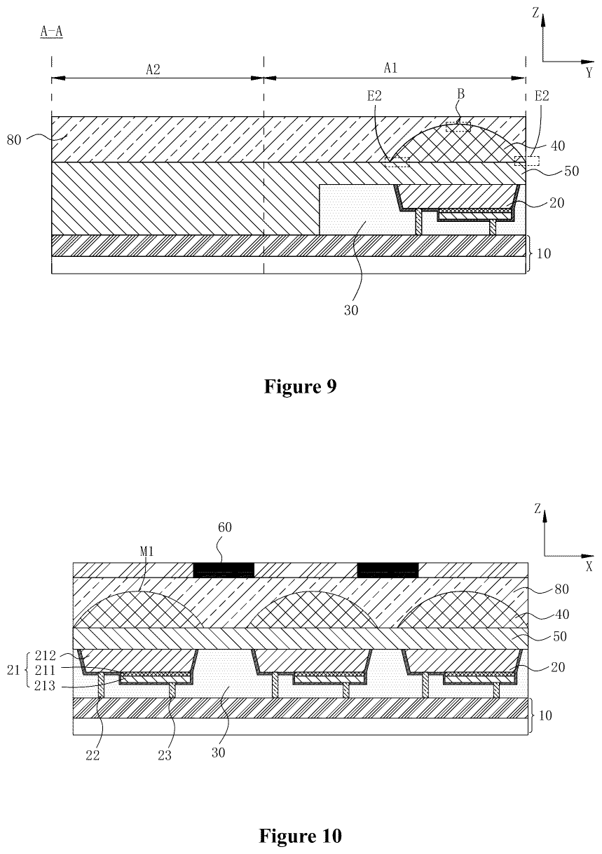

In some embodiments, reference is made to FIGS. 8 and 9, the display panel includes an active area A1 and a transparent area A2. The active area A1 and the transparent area A2 are arranged along the second direction Y, and the light-emitting device 20 is disposed in the active area A1, the second direction Y is parallel to the plane of the substrate 10. The planarization part 50 includes a transparent material, and a part of the planarization part 50 is located in the transparent area A2.

The active area A1 in the display panel is configured to implement the display function. The transparent area A2 in the display panel has high transmittance, which can improve the light transmittance of the display panel and the display panel can be a transparent display panel. The active area A1 and the transparent area A2 are arranged along the second direction Y. Specific positional relationship between the active area A1 and the transparent area A2 is not limited herein. In an embodiment, there are multiple active areas A1 and transparent areas A2, and the multiple active areas A1 and the multiple transparent areas A2 are alternately arranged in the second direction Y.

The light-emitting device 20 is disposed in the active area A1, and generally no light-emitting device 20 is disposed in the transparent area A2. The light-emitting devices 20 in the active area A1 may be arranged side by side along the first direction X, which is a direction that intersects the second direction Y. In one embodiment, the first direction is perpendicular to the second direction Y. Furthermore, the light-emitting devices 20 in the active area A1 may be arranged only along the first direction X, or may be arranged side by side along the first direction X and the second direction Y at the same time, which is not limited herein.

In addition to the light-emitting device 20, the light reflecting part 30 and the light adjusting part 40 may not be disposed in the light transmitting region A2, that is, the light reflecting part 30 and the light adjusting part 40 may be disposed only in the active area A1.

In an embodiment, since the planarization part 50 includes a transparent material, the planarization part 50 can meet a need for light transmission. Furthermore, a part of the planarization part 50 may be disposed in the active area A1, another part of the planarization part 50 may be disposed in the transparent area A2, and a flat and continuous film structure may be formed in the active area A1 and the transparent area A2 at the same time by means of the planarization part 50, thereby meeting the needs of transparent display while reducing the difficulty of preparing the films in the active area A1 and the transparent area A2 on a basis of meeting requirements of the transparent display.

In other embodiments, the display panel may not include the transparent area A2. That is, the embodiments of the present disclosure may be applicable to transparent display panels, or may also be applicable to conventional non-transparent display panels, which is not limited in the embodiments of the present disclosure.

Furthermore, the display panel further includes a transparent adhesive layer 80. The transparent adhesive layer 80 may be located in both the active area A1 and the transparent area A2. In the active area A1, at least part of the transparent adhesive layer 80 is separated from the planarization part 50 through the light adjusting part 40. In the transparent area A2, the transparent adhesive layer 80 and the planarization part 50 are arranged attached to each other.

In some embodiments, reference is made to FIGS. 6 and 10, at least part of the light-emitting devices 20 are spaced apart in a first direction X, which is parallel to the plane of the substrate 10. In the first direction X, the first surface M1 includes two opposite first edges E1. In a direction from a center B of the first surface M1 to the first edge E1, a distance between the first surface M1 and the substrate 10 gradually decreases.

The first edge E1 is an edge of the light-emitting device 20 in the first direction X, where the first edge E1 may extend along the second direction Y. In the first direction X, there are two first edges E1, the center B of the first surface M1 is located at the center of the two first edges E1.

Furthermore, in an embodiment, the shape of the first surface M1 is adjusted and the distance between the first surface M1 and the substrate 10 is gradually decreased in the direction from the center B of the first surface M1 to the first edge E1. That is, the cross-sectional shape of the first surface M1 of the light adjusting part 40 in the first direction X and the thickness direction Z may include an arc-shaped structure protruding in a direction away from the substrate 10, thereby facilitating achieving the light gathering effect of the light adjusting part 40 through the arc-shaped structure, thereby improving the light utilization of the display panel.

In some embodiments, reference is made to FIGS. 8 and 9, in the second direction Y, the first surface M1 includes two opposite edges. In the direction pointing from the center B of the first surface M1 to the direction of the second edge E2, the distance between the first surface M1 and the substrate 10 gradually decreases, the second direction Y is parallel to the plane of the substrate 10 and intersects with the first direction X.

The second edge E2 is an edge of the light-emitting device 20 in the second direction Y, where the second edge E2 may extend along the first direction X. There are two second edges E2. The center B of the first surface M1 is located at the center of the two second edges E2. That is, in the second direction Y, the two second edges E2 are respectively located on both sides of the center B of the first surface M1.

Based on the foregoing content, the cross-sectional shape of the first surface M1 of the light adjusting part 40 in the first direction X and the thickness direction Z may include an arc-shaped structure protruding in a direction away from the substrate 10. Furthermore, the first surface M1 is further adjusted and the distance between the first surface M1 and the substrate 10 gradually decreases in the direction from the center B of the first surface M1 to the second edge E2. Furthermore, the cross-sectional shape of the first surface M1 of the light adjusting part 40 in the second direction Y and the thickness direction Z may include an arc-shaped structure protruding in a direction away from the substrate 10.

This design allows the first surface M1 to have a certain curve in both the first direction X and the second direction Y, thereby further improving the light gathering effect of the light adjusting part 40 and improving the light utilization of the display panel.

In some embodiments, an orthographic projection of a light-emitting device 20 on the substrate 10 overlaps the orthographic projection of a light adjusting part 40 on the substrate 10.

In an embodiment, one light adjusting part 40 is provided for only one light-emitting device 20, and the one light adjusting part 40 is only configured to adjust the propagation direction of light emitted by one light-emitting device 20, thereby reducing the risk of light emitted by different light-emitting devices 20 entering the same light adjusting part 40, thereby reducing the risk of crosstalk between light of different colors and improving display reliability. In an embodiment, the orthographic projection of one light adjusting part 40 on the substrate 10 covers the orthographic projection of one light-emitting device 20 on the substrate 10.

In some embodiments, reference is made to FIG. 10, the display panel further includes a light-shielding part 60 disposed on the side of the light-emitting device 20 away from the substrate 10. The orthographic projection of the light-shielding part 60 on the substrate 10 is at least partially located between the orthographic projection of the adjacent light adjusting part 40 on the substrate 10.

The light-shielding part 60 includes a light-shielding material. The light propagating to the light-shielding part 60 may be absorbed by the light-shielding part 60. In one embodiment, the light-shielding part 60 may include a light-absorbing material. The orthographic projection of the light-shielding part 60 on the substrate 10 is at least partially located between the orthographic projections of adjacent light adjusting parts 40 on the substrate 10, where in the thickness direction Z, the light-shielding part 60 and the light adjusting part 40 may be located at the same height. In one embodiment, in the thickness direction Z, the light-shielding part 60 may be located on the side of the light adjusting part 40 facing the substrate 10 or away from the substrate 10, which is not limited herein.

Based on the forgoing content, the forward beams emitted by the light-emitting device 20 may propagate to the light adjusting part 40. For example, the lateral beams or other light, except the forward beams, may be reflected by the light reflecting part 30 to change the propagation direction and be transferred to the light adjusting part 40. However, some light may still propagate to the region between adjacent light adjusting parts 40, and light of different colors may be mixed in this region.

In view of the above, a light-shielding part 60 is further provided herein. The orthographic projection of the light-shielding part 60 on the substrate 10 is at least partially located between the orthographic projections of the adjacent light adjusting parts 40 on the substrate 10, thus at least part of the light that propagates to the region between adjacent light adjusting parts 40 may be absorbed by the light-shielding part 60, thereby reducing the light crosstalk and improving display reliability.

The positional relationship between the light-shielding part 60 and the light-emitting device 20 is not limited herein. The orthographic projection of the light-shielding part 60 on the substrate 10 may be completely located between the orthographic projections of the adjacent light-emitting devices 20 on the substrate 10, or the orthographic projection of the light-shielding part 60 on the substrate 10 may partially overlap the orthographic projection of the light-emitting device 20 on the substrate 10.

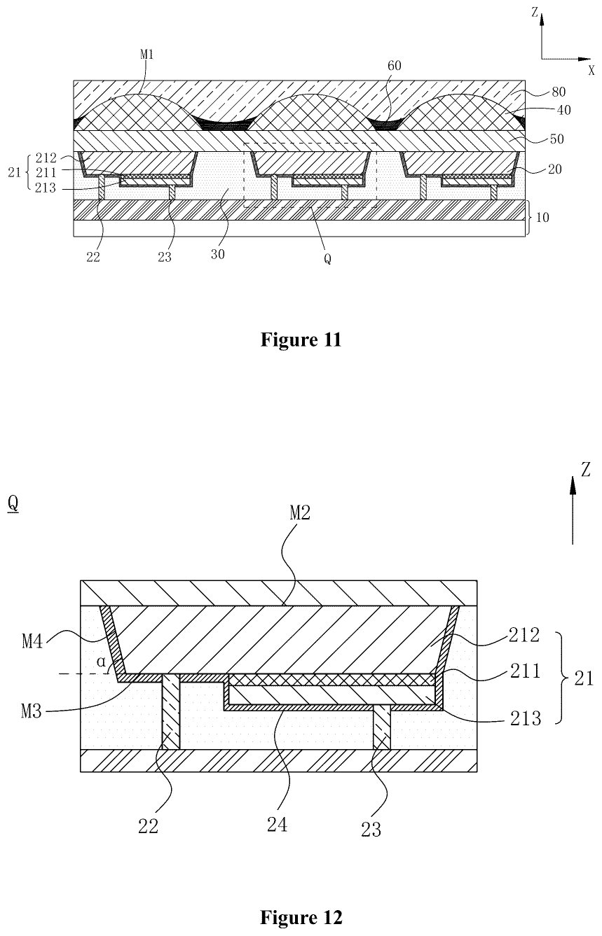

In some embodiments, reference is made to FIG. 11, the light-shielding part 60 is located on the same layer as the light adjusting part 40.

In the thickness direction Z, at least part of the structure of the light-shielding part 60 is located at the same height as the light adjusting part 40. The light-shielding part 60 may be disposed close to the light adjusting part 40, or the light-shielding part 60 may be spaced apart from the light adjusting part 40 in a direction parallel to the plane of the substrate 10.

In an embodiment, the light-shielding part 60 and the light adjusting part 40 are arranged in the same layer, which may reduce the occupation of the light-shielding part 60 for other film structures, reducing the difficulty of designing and manufacturing the display panel. This can also improve the cooperation effect between the light adjusting part 40 and the light-shielding part 60, and much light propagating to the adjacent light adjusting parts 40 can be absorbed by the light-shielding part 60, thereby further reducing the risk of light crosstalk and improving the display reliability.

In some embodiments, as shown in FIG. 11, the orthographic projection of the light-shielding part 60 on the substrate 10 overlaps the orthographic projection of the light-emitting device 20 on the substrate 10.

In an embodiment, the orthographic projection of the light-shielding part 60 on the substrate 10 overlaps the orthographic projection of the light-emitting device 20 on the substrate 10, and the light-shielding part 60 may completely cover the region between adjacent light-emitting devices 20. Therefore, the light-shielding part 60 can absorb more light propagating to the region between adjacent light-emitting devices 20, thereby reducing the risk of light emitted by different light-emitting devices 20 being mixed and cross-talked in the region between adjacent light-emitting devices 20, thereby facilitating improving the display accuracy of the display panel.

In some embodiments, the orthographic projection of the light-shielding part 60 on the substrate 10 overlaps the orthographic projection of the light adjusting part 40 on the substrate 10.

The light adjusting part 40 is configured to cooperate with the light reflecting part 30 to convert a part of the lateral beams into the forward beams, thereby improving the light utilization of the display panel. However, part of the light entering the light adjusting part 40 may exit from the edge of the light adjusting part 40 in a direction parallel to the plane of the substrate 10 due to the influence of various factors, which may also easily lead to the risk of crosstalk between different colors of light.

In an embodiment, the orthographic projection of the light-shielding part 60 on the substrate 10 overlaps the orthographic projection of the light adjusting part 40 on the substrate 10. That is, the orthographic projection of the light-shielding part 60 on the substrate 10 may overlap with the orthographic projection of an edge position of the light adjusting part 40 on the substrate 10 which is parallel to plane direction of the substrate 10, and the light-shielding part 60 can absorb part of the light emitted from the edge position of the light adjusting part 40, thereby reducing the risk of light crosstalk and improving the display effect.

Furthermore, in some embodiments, the light-shielding part 60 is attached to edges of the light adjusting part 40 which are parallel to the plane of the substrate 10.

The formation method of the light-shielding part 60 is not limited herein. In an embodiment, the light-shielding part 60 may be formed by coating. Furthermore, the light-shielding part 60 may have a certain fluidity, and a distance between the surface of the light-shielding part 60 away from the substrate 10 and the surface of the planarization part 50 away from the substrate 10 first gradually decreases, and then gradually increases in a direction from one of the light adjusting parts 40 to the adjacent light adjusting part 40.

In some embodiments, reference is made to FIGS. 11 and 12, the light-emitting device 20 includes a light-emitting part 21, which includes a first semiconductor layer 212 and a second semiconductor layer 213 located on one side of the first semiconductor layer 212 facing the substrate 10. The first semiconductor layer 212 includes a second surface M2 away from the substrate 10 and a third surface M3 facing the substrate 10. The orthographic projection of the second surface M2 on the substrate 10 at least partially exceeds the orthographic projection of the third surface M3 on the substrate 10.

The first semiconductor layer 212 has the second surface M2 and the third surface M3 which are opposite in the thickness direction Z. The second surface M2 is located on the side of the first semiconductor layer 212 away from the substrate 10, and the third surface M3 is located on the side of the first semiconductor layer 212 facing the substrate 10. The dimensions of the second surface M2 and the third surface M3 are not exactly the same, and the orthographic projection of the second surface M2 on the substrate 10 at least partially exceeds the orthographic projection of the third surface M3 on the substrate 10.

Reference is made to FIG. 12, the “at least partially exceed” mentioned here may only mean that a left edge of the second surface M2 exceeds the third surface M3. In this case, a left sidewall of the first semiconductor layer 212 is inclined relative to the thickness direction Z. In one embodiment, only a right edge of the second surface M2 may be disposed beyond the third surface M3. In this case, the right sidewall of the first semiconductor layer 212 is inclined relative to the thickness direction Z. In one embodiment, the left edge and the right edge of the second surface M2 may both be disposed beyond the third surface M3. In this case, the left sidewall and the right sidewall of the first semiconductor layer 212 are inclined relative to the thickness direction Z. FIG. 12 shows a situation where the left edge and the right edge of the second surface M2 are both disposed beyond the third surface M3.

In an embodiment, the orthographic projection of the second surface M2 on the substrate 10 covers and exceeds the orthographic projection of the third surface M3 on the substrate 10. That is, the size of the second surface M2 may be larger than the size of the third surface M3.

Reference is made to the foregoing figures, a cross-sectional shape of the first semiconductor layer 212 is not a rectangular structure, but an inverted trapezoidal structure. That is, the first semiconductor layer 212 includes a fourth surface M4 connecting the second surface M2 and the third surface M3. The fourth surface M4 is not parallel to the thickness direction Z, but intersects the thickness direction Z.

In an embodiment, the light emitted by the light-emitting layer 211 may propagate into the first semiconductor layer 212 and exit from the light-emitting device 20 through the first semiconductor layer 212. On this basis, the orthographic projection of the second surface M2 on the substrate 10 covers and exceeds the orthographic projection of the third surface M3 on the substrate 10 through the second surface M2 and the third surface M3 with different sizes. The first semiconductor layer 212 under this design has a certain light-condensing effect, for more light to exit the light-emitting device 20 from the second surface M2 instead of from the third surface M3 or the fourth surface M4, thereby improving the light utilization and improving the display brightness of the display panel to improve the display effect.

In some embodiments, reference is made to FIGS. 11 and 12, the first semiconductor layer 212 includes a fourth surface M4 connecting the second surface M2 and the third surface M3. The angle α between the fourth surface M4 and the plane of the substrate 10 satisfies 80°≤α≥90°.

The size of the angle α between the fourth surface M4 and the substrate 10 may affect the light-gathering ability of the first semiconductor layer 212. In a case that a is too large, the light-gathering ability of the first semiconductor layer 212 may be insufficient, and the light easily exits the display device from the fourth surface M4, which is not conducive to the light utilization of the display panel. At the process level, in a case that a is too large, it is difficult to meet the process preparation requirements, may not achieve mass production, and easily leads to a low production yield of the light-emitting device 20. In a case that a is too small, the light-emitting device 20 may be broken easily during the transferring process, the reliability and service life of the light-emitting device 20 are affected.

In summary, the angle α between the fourth surface M4 and the substrate 10 is limited herein, and α is no less than 80° and no more than 90°, thereby improving the production yield and usage reliability of the light-emitting device 20 and having strong practicability on a basis of satisfying the light-gathering function of the first semiconductor layer 212.

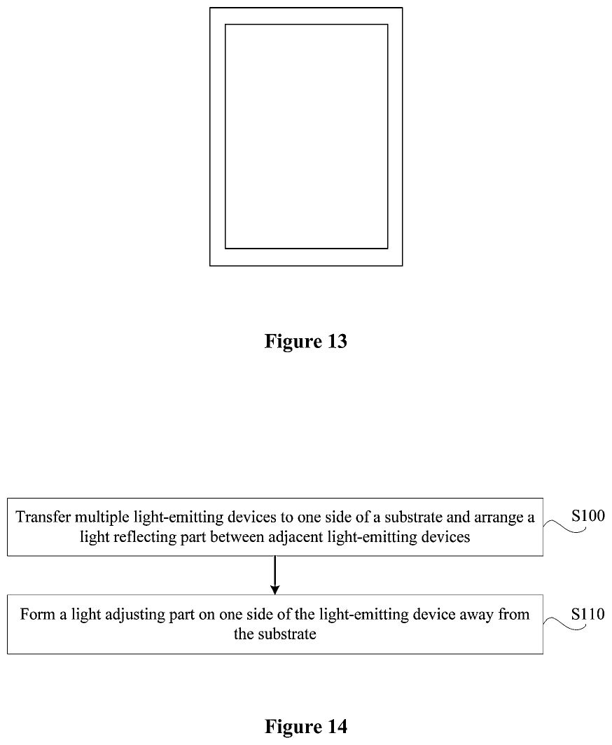

In one embodiment, reference is made to FIG. 13, a display device is provided according to an embodiment of the present disclosure. The display device includes the display panel according to any one of the aforementioned embodiments.

In an embodiment, the display device has beneficial effects of the display panel in any one of the foregoing embodiments. For details, the beneficial effects of the display panel are described in the foregoing embodiment, which is not repeated again. For example, the display device includes but is not limited to mobile phones, computer screens, tablets, vehicle-mounted displays and other devices that need to display and emit light.

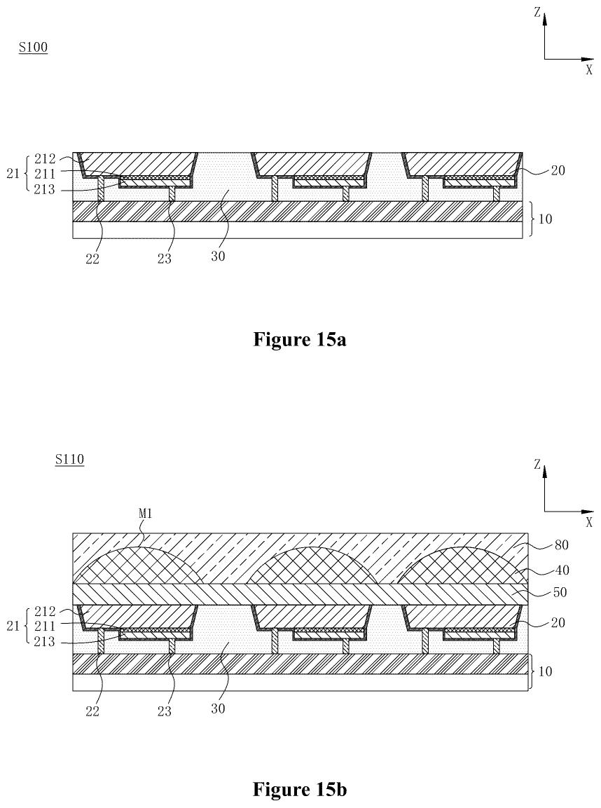

In one embodiment, reference is made to FIGS. 14 and 15, a method for manufacturing a display panel is provided according to an embodiment of the present disclosure. The method includes following steps.

In S100, multiple light-emitting devices are transferred to one side of the substrate, where the light reflecting part is disposed between adjacent light-emitting devices.

Reference is made to FIG. 15a, in the step S100, the substrate 10 mainly plays a supporting role, and the light-emitting device 20 and the light reflecting part 30 are transferred or formed on a same side of the substrate 10. The light-emitting device 20 is a main structure configured to achieve the display effect. The light reflecting part 30 includes a reflective material. At least part of the lateral beams emitted by the light-emitting device 20 may reach the light reflecting part 30 and be reflected by the light reflecting part 30 to change the direction of light propagation.

The transferring or formation of the light-emitting device 20 and the light reflecting part 30 on the substrate 10 are not limited herein. For example, the light reflecting part 30 may be formed on the substrate 10 first, then the light-emitting device 20 may be transferred to the substrate 10. In one embodiment, the light-emitting device 20 may be transferred to the substrate 10 first, then the light reflecting part 30 may be formed on the substrate 10. In one embodiment, the light reflecting part 30 and the light-emitting device 20 may be integrated together first, and then the whole composed of the two may be transferred to the substrate 10 together.

In S110, a light adjusting part is formed on one side of the light-emitting device away from the substrate.

Reference is made to FIG. 15b, in step S110, the orthographic projection of the light adjusting part 40 on the substrate 10 overlaps the orthographic projection of the light-emitting device 20 on the substrate 10. The light adjusting part 40 includes a first surface M1 away from the substrate 10. The first surface M1 protrudes away from the substrate 10. In this way, the cross-sectional structure of the light adjusting part 40 may be in a shape similar to a convex lens, and the light adjusting part 40 may have a certain light gathering effect. Furthermore, the light reflected by the light reflecting part 30 and reaching the light adjusting part 40 may be converged by the light adjusting part 40, and at least part of the light emitted by the light-emitting device 20 may be converted into the forward beams with the cooperation of the light reflecting part 30 and the light adjusting part 40, thereby improving the light utilization of the display panel.

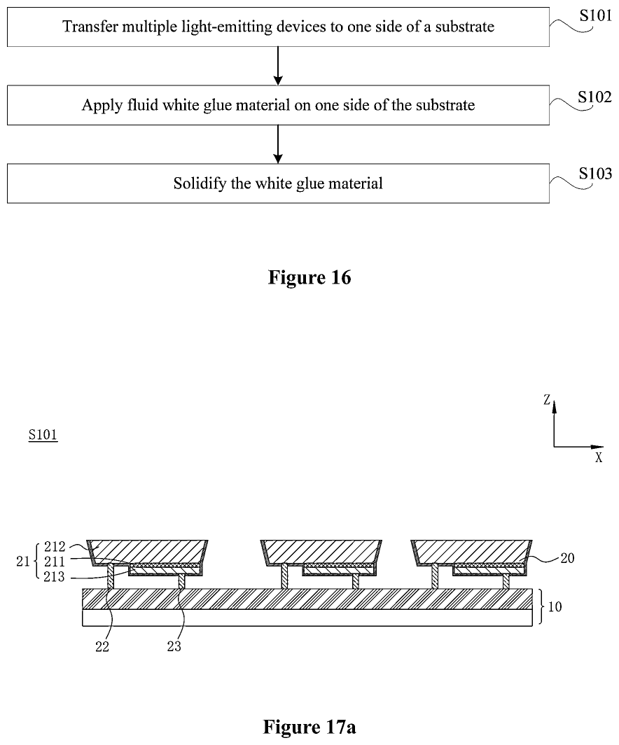

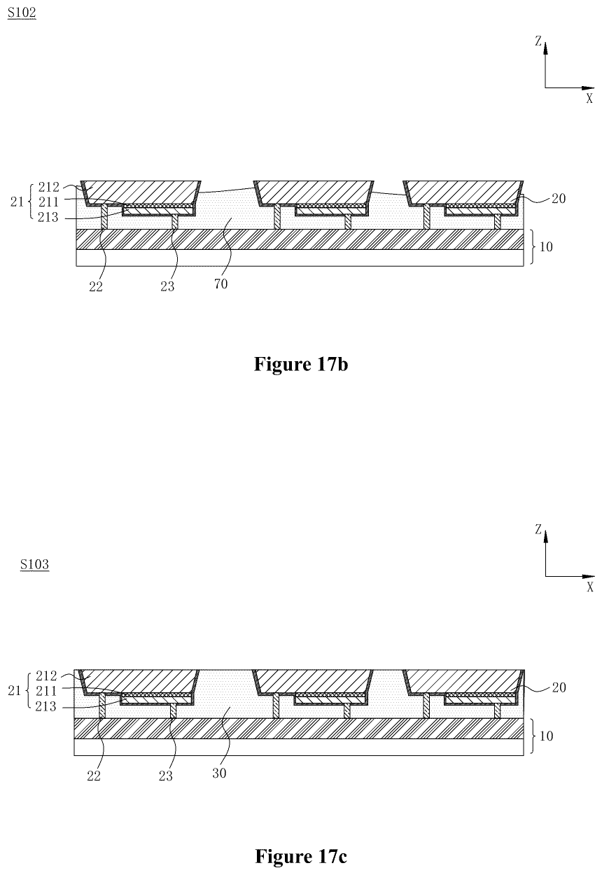

In some embodiments, reference is made to FIGS. 16 and 17, the step S100 include the following steps.

In S101, multiple light-emitting devices are transferred to one side of the substrate.

Reference is made to FIG. 17a, in step S101, the light-emitting device 20 is transferred to the side of the substrate 10 in priority to the light reflecting part, and multiple light-emitting devices 20 are arranged at intervals from each other. In one embodiment, the multiple light-emitting devices 20 may include a red light-emitting device 20 for emitting red light, a green light-emitting device 20 for emitting green light, and a blue light-emitting device 20 for emitting blue light.

In S102, the fluid white glue material is disposed on one side of the substrate 10.

Reference is made to FIG. 17b, in step S120, since the white glue material 70 is fluid, the white glue material 70 may have a certain fluidity, and at least some of gaps between adjacent light-emitting devices 20 are filled with the white glue material. Furthermore, the light-emitting device 20 includes a light-emitting part 21, a first electrode 22 and a second electrode 23 located on one side of the light-emitting part 21 facing the substrate 10. A part of the white glue material 70 may be moved between the first electrode 22 and the second electrode 23 in the same light-emitting device 20.

In S103, the white glue material is solidified.

Reference is made to FIG. 17c, in step S103, the light reflecting part 30 may be formed by solidifying the white glue material. Furthermore, the light reflecting part 30 is attached to the light-emitting device 20.

In an embodiment, the light reflecting part 30 is formed on one side of the substrate 10 after the light-emitting device 20 is transferred. The transferring process of the light-emitting device 20 may not be affected by the light reflecting part 30 or the white glue material, which is conductive to reduction in the difficulty of manufacturing display panels and improvement in the yield rate of display panels. In addition, the light-emitting device 20 is attached to the light reflecting part 30, which facilitates reducing the distance relationship between the light reflecting part 30 and the light-emitting device 20, and more lateral beams emitted by the light-emitting device 20 can be reflected by the light reflecting part 30 and converged by the light adjusting part 40, thereby improving the light extraction efficiency of the display panel.

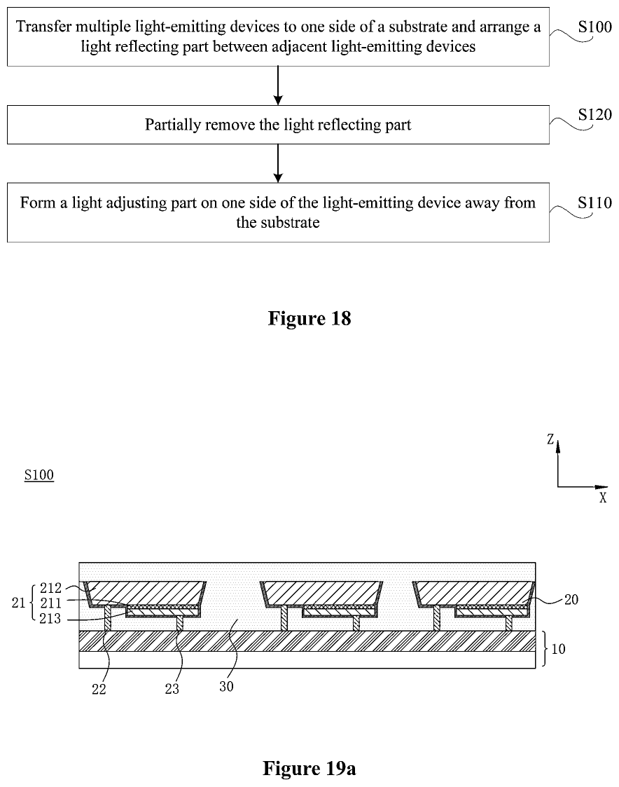

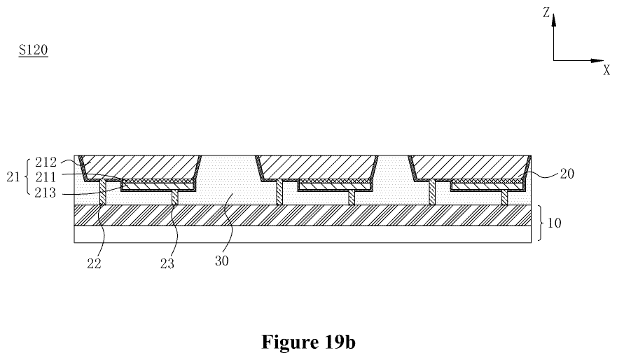

In some embodiments, reference is made to FIG. 18 and FIG. 19, before the step S110, the method also includes the following steps.

In S120, the light reflecting part 30 is partially removed.

Reference is made to FIG. 19a, the light reflecting part 30 formed in step S100 may be partially disposed on one side of the light-emitting device 20 away from the substrate 10 due to the influence of factors such as the prepare process, which will affect the normal light emission of the light-emitting device 20.

Reference is made to FIG. 19b, in step S120, he light reflecting part 30 is partially removed by etching or other processes, and the light reflecting part 30 does not exceed the surface of the light-emitting device 20 away from the substrate 10. That is, the distance between the surface of the light reflecting part 30 away from the substrate 10 and the substrate 10 is not greater than the distance between the surface of the light-emitting device 20 away from the substrate 10 and the substrate 10. This reduces the overall size of the light reflecting part 30 and the light-emitting device 20 in the thickness direction Z, thereby reducing the overall thickness of the display panel and facilitating a thin and light design of the display panel.

Although embodiments disclosed in the present disclosure are as above, the described content is only an embodiment adopted to facilitate understanding of the present disclosure and is not intended to limit the present disclosure. Any modifications and changes in the form and details of the implementation without departing from the spirit and scope disclosed in the present disclosure. However, the protection scope of the present disclosure must still be subject to the scope defined by the appended claims.

The above is only a specific implementation mode of the present disclosure. The replacement of other connection methods described above can refer to the corresponding ones in the foregoing method embodiments for the convenience and simplicity of description, which will not be described again here. The protection scope of the present disclosure is not limited thereto. Various equivalent modifications or substitutions within the scope disclosed in the present disclosure, and these modifications or substitutions should be covered within the protection scope of the present disclosure.

1. A display panel, comprising:
a substrate;
light-emitting devices, spaced on one side of the substrate;
a light reflecting part, at least partially located between adjacent light-emitting devices; and
a light adjusting part, disposed on one side of the light-emitting devices away from the substrate, wherein an orthographic projection of the light adjusting part on the substrate overlaps an orthographic projection of the corresponding light-emitting device on the substrate, the light adjusting part comprises a first surface away from the substrate, and the first surface protrudes away from the substrate.

2. The display panel according to claim 1, wherein
the light reflecting part is partially located on one side of the light-emitting devices facing the substrate; and wherein the light-emitting device comprises:
a light-emitting part; and
a first electrode and a second electrode at least partially disposed on one side of the light-emitting part facing the substrate, wherein the light reflecting part is partially located between the first electrode and the second electrode of the same light-emitting device.

3. The display panel according to claim 1, wherein
the light reflecting part is attached to the light-emitting devices.

4. The display panel according to claim 3, wherein
the light reflecting part comprises reflecting divisions, the reflecting divisions are attached to the light-emitting devices in a first direction, and adjacent reflecting divisions are spaced, and the first direction is parallel to a plane where the substrate is located.

5. The display panel according to claim 1, wherein
a distance between a surface of the light reflecting part away from the substrate and the substrate is not greater than a distance between a surface of the light-emitting device away from the substrate and the substrate, in a thickness direction of the substrate.

6. The display panel according to claim 1, wherein
the light reflecting part comprises white glue.

7. The display panel according to claim 1, further comprising:
a planarization part disposed between the light adjusting part and the light-emitting devices in a thickness direction of the substrate.

8. The display panel according to claim 7, wherein
a refractive index of the planarization part is smaller than a refractive index of the light adjusting part; or
the light-emitting device comprises a light-emitting layer, and a refractive index of the light-emitting layer is greater than the refractive index of the light adjusting part.

9. The display panel according to claim 7, wherein
the planarization part is partially stuffed between adjacent light-emitting devices.

10. The display panel according to claim 7, wherein
the display panel comprises an active area and a transparent area, the active area and the transparent area are arranged along a second direction, the light-emitting devices are arranged in the active area, and the second direction is parallel to a plane where the substrate is located; and
the planarization part is made of transparent material, and is partially located in the transparent area.

11. The display panel according to claim 1, wherein
at least some of the light-emitting devices are spaced in a first direction, and the first direction is parallel to a plane where the substrate is located; and
the first surface comprises two opposite first edges in the first direction, a distance between the first surface and the substrate gradually decreases from a center of the first surface to the first edges of the first surface.

12. The display panel according to claim 11, wherein
the first surface comprises two opposite second edges in a second direction, the distance between the first surface and the substrate gradually decreases from the center of the first surface to the second edges of the first surface, and the second direction is parallel to the plane of the substrate and intersects with the first direction.

13. The display panel according to claim 1, further comprising:
a light-shielding part disposed on one side of the light-emitting devices away from the substrate, wherein an orthographic projection of the light-shielding part on the substrate is at least partially located between orthographic projections of adjacent light adjusting parts on the substrate.

14. The display panel according to claim 13, wherein
the light-shielding part and the light adjusting part are arranged on a same layer.

15. The display panel according to claim 13, wherein
the orthographic projection of the light-shielding part on the substrate overlaps the orthographic projection of the light-emitting devices on the substrate; or
the orthographic projection of the light-shielding part on the substrate overlaps the orthographic projection of the light adjusting part on the substrate.

16. The display panel according to claim 1, wherein
the light-emitting device comprises a light-emitting part, the light-emitting part comprises a first semiconductor layer and a second semiconductor layer located on one side of the first semiconductor layer facing the substrate;
the first semiconductor layer comprises a second surface away from the substrate and a third surface facing the substrate, an orthographic projection of the second surface on the substrate at least partially exceeds an orthographic projection of the third surface on the substrate; and
the first semiconductor layer comprises a fourth surface connecting the second surface and the third surface, the fourth surface is at an angle α to a plane where the substrate is located, and α is greater than or equal to 80° and less than or equal to 90°.

17. A display device, comprising: a display panel, wherein the display panel comprises:
a substrate;
light-emitting devices, spaced on one side of the substrate;
a light reflecting part, at least partially located between adjacent light-emitting devices; and
a light adjusting part, disposed on one side of the light-emitting devices away from the substrate, wherein an orthographic projection of the light adjusting part on the substrate overlaps an orthographic projection of the corresponding light-emitting device on the substrate, the light adjusting part comprises a first surface away from the substrate, and the first surface protrudes away from the substrate.

18. A method for manufacturing a display panel, comprising:
transferring light-emitting devices to one side of a substrate and arranging a light reflecting part between the adjacent light-emitting devices; and
forming a light adjusting part on one side of the light-emitting device away from the substrate, wherein an orthographic projection of the light adjusting part on the substrate overlaps an orthographic projection of the light-emitting device on the substrate, the light adjusting part comprises a first surface away from the substrate, and the first surface protrudes away from the substrate.

19. The method according to claim 18, wherein the transferring light-emitting devices to one side of the substrate and arranging the light reflecting part between the adjacent light-emitting devices comprises:
spacing the light-emitting devices on the side of the substrate;
applying fluid white glue material on the side of the substrate, wherein the fluid white glue material is at least stuffed between the adjacent light-emitting devices; and
solidifying the white glue material to form the light reflecting part, and the light reflecting part is attached to the light-emitting devices.

20. The method according to claim 18, further comprising:
partially removing the light reflecting part to limit the light reflecting part to a surface where the light-emitting devices is away from the substrate before the forming the light adjusting part on the side of the light-emitting device away from the substrate.
